(19) United States
(12) Patent Application Publication
(10) Pub. No.: US 2026/0037695 A1
(43) Pub. Date: Feb. 5, 2026

(54) DRILLING PLANNING SYSTEM WITH INTEGRATED KNOWLEDGE MANAGEMENT SYSTEM AND METHOD FOR USING THE SAME

(71) Applicant: Schlumberger Technology Corporation, Sugar Land, TX (US)

(72) Inventors: Valerian Guillot, Montpellier (FR); Nata Franco, Al-Khobar (SA); Mauricio Corona, Al-Khobar (SA)

(21) Appl. No.: 18/794,209

(22) Filed: Aug. 5, 2024

(51) Int. Cl. G06F 30/27; G06N 5/02

(52) U.S. Cl. CPC G06F 30/27; G06N 5/02

(57) ABSTRACT

A method for automatically determining mitigation and prevention measures that are related to a wellsite action. The method includes obtaining a plurality of characteristics of the wellsite action, inputting the plurality of characteristics into a graphical interface, and generating a plurality of risks that correspond to the plurality of characteristics and then displaying risks on the graphical interface. Next, the associated risks are converted into a query vector within a knowledge bank. The knowledge bank is then queried to provide a mitigation or prevention measure relevant to the query vector. Specifically, an approximate nearest neighbor search may be used which finds a vector representing a mitigation or prevention measure that is closest to the query vector. The method also includes displaying the mitigation or prevention measure within the graphical interface so that a user may perform a wellsite action in response to the displayed mitigation or prevention measure.

### BACKGROUND

When planning a well section or other wellsite action, it is useful to plan for any associated risks and identify quickly what mitigation or prevention measures may be applied based on the characteristics of the planned well. Currently, identifying mitigation and prevention measures consists of relying on the individual experience of the user or engineer planning the well section, or for the user to manual search through a knowledge management system or database such as InTouch™, Google®, or the like.

The workflow in current drilling planning systems includes representing the occurrence of a risk in a graphical representation. The user then manually decides to add risks to a risk register based on the mitigation or prevention means they are planning to apply to the planned well section.

With the implementation of InTouch™ in the late 1990s, a leap in knowledge management was achieved and helped to create organizations that are structured around established standard operating procedures, lessons learned, and best practices. However, artificial intelligence and natural language learning have evolved with the 2018 introduction of semantic models that are revolutionizing the way knowledge is retrieved.

What is needed is a system and method to automatically identify mitigation and prevention measures that are relevant to a planned well section or other wellsite action.

### SUMMARY

The current disclosure provides a method for automatically determining mitigation and prevention measures that are related to a wellsite action. According to certain embodiments, the method includes obtaining a plurality of characteristics of the wellsite action, generating a plurality of risks that correspond to the plurality of characteristics, converting the plurality of risks into a query vector within a knowledge bank, and then querying the knowledge bank to provide at least one mitigation or prevention measure in response to the query vector. The plurality of characteristics of the wellsite action may include a depth of a planned section of a well, a formation of a planned section of the well, a diameter of a planned section of a well, a tool to be used in a planned section of the well, a field of a planned section of a well, or a shape of a planned section of a well. In certain embodiments, generating the plurality of risks includes automatically incorporating at least one known risk associated with at least one offset well, or manually inputting at least one known risk by the user. In certain embodiments, the method also includes performing a wellsite action by generating or transmitting a signal that instructs or causes an action to occur, wherein the action comprises a physical action, and wherein the physical action comprises selecting where to drill a wellbore in a subsurface formation, drilling the wellbore, varying a trajectory of the wellbore, varying a weight or torque on a drill bit that is drilling the wellbore, varying a rate or concentration of a fluid being pumped into the wellbore, or a combination thereof.

According to certain embodiments, the method further includes inputting the plurality of characteristics into a graphical interface, displaying the plurality of risks on the graphical interface; and displaying the mitigation or prevention measure on the graphical interface. Inputting the plurality of characteristics into the graphical interface may be performed by manually inputting the plurality of characteristics, or by automatically receiving an input from a tool, system, or sensor associated with the wellsite action.

According to certain embodiments, querying the knowledge bank to provide at least one mitigation or prevention measure relevant to the query vector includes performing a semantic search within the knowledge bank, specifically by performing an approximate nearest neighbor search within the knowledge bank. In certain embodiments, the method specifically includes performing a search for three closest vectors within the knowledge bank relative to the query vector in order to provide the at least one mitigation or prevention measure that is the most relevant to the query vector. The three closest vectors within the knowledge bank relative to the query vector may include a proximity of a known risk to the planned well section, a severity of a known risk related to the planned well section, a probability of risk occurring in the planned well section, or a combination thereof.

It will be appreciated that this summary is intended merely to introduce some aspects of the present methods, systems, and media, which are more fully described and/or claimed below. Accordingly, this summary is not intended to be limiting.

### BRIEF DESCRIPTION OF THE DRAWINGS

The accompanying drawings, which are incorporated in and constitute a part of this specification, illustrate embodiments of the present teachings and together with the description, serve to explain the principles of the present teachings. In the figures:

FIG. 1 illustrates an example of a system that includes various management components to manage various aspects of a geologic environment, according to an embodiment.

FIG. 2 illustrates a schematic flow diagram depicting how mitigation or prevention measures related to a wellsite action are manually added to a graphical interface, according to an embodiment.

FIG. 3 illustrates a graphical interface incorporating a visual schematic of an approximate nearest neighbor search used to search for mitigation or prevention measures related to a wellsite action, according to an embodiment.

FIG. 4 illustrates a database used in a knowledge bank that is searched to provide mitigation or prevention measures related to a wellsite action, according to an embodiment.

FIG. 5 illustrates a flowchart of a method for automatically determining mitigation and prevention measures related to a wellsite action, according to an embodiment.

FIG. 6 illustrates a schematic view of a computing system for performing at least a portion of the method(s) described herein, according to an embodiment.

### DETAILED DESCRIPTION

Reference will now be made in detail to embodiments, examples of which are illustrated in the accompanying drawings and figures. In the following detailed description, numerous specific details are set forth in order to provide a thorough understanding of the invention. However, it will be apparent to one of ordinary skill in the art that the invention may be practiced without these specific details. In other instances, well-known methods, procedures, components, circuits, and networks have not been described in detail so as not to unnecessarily obscure aspects of the embodiments.

It will also be understood that, although the terms first, second, etc. may be used herein to describe various elements, these elements should not be limited by these terms. These terms are only used to distinguish one element from another. For example, a first object or step could be termed a second object or step, and, similarly, a second object or step could be termed a first object or step, without departing from the scope of the present disclosure. The first object or step, and the second object or step, are both, objects or steps, respectively, but they are not to be considered the same object or step.

The terminology used in the description herein is for the purpose of describing particular embodiments and is not intended to be limiting. As used in this description and the appended claims, the singular forms “a,” “an” and “the” are intended to include the plural forms as well, unless the context clearly indicates otherwise. It will also be understood that the term “and/or” as used herein refers to and encompasses any possible combinations of one or more of the associated listed items. It will be further understood that the terms “includes,” “including,” “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Further, as used herein, the term “if” may be construed to mean “when” or “upon” or “in response to determining” or “in response to detecting,” depending on the context.

Attention is now directed to processing procedures, methods, techniques, and workflows that are in accordance with some embodiments. Some operations in the processing procedures, methods, techniques, and workflows disclosed herein may be combined and/or the order of some operations may be changed.

### System Overview

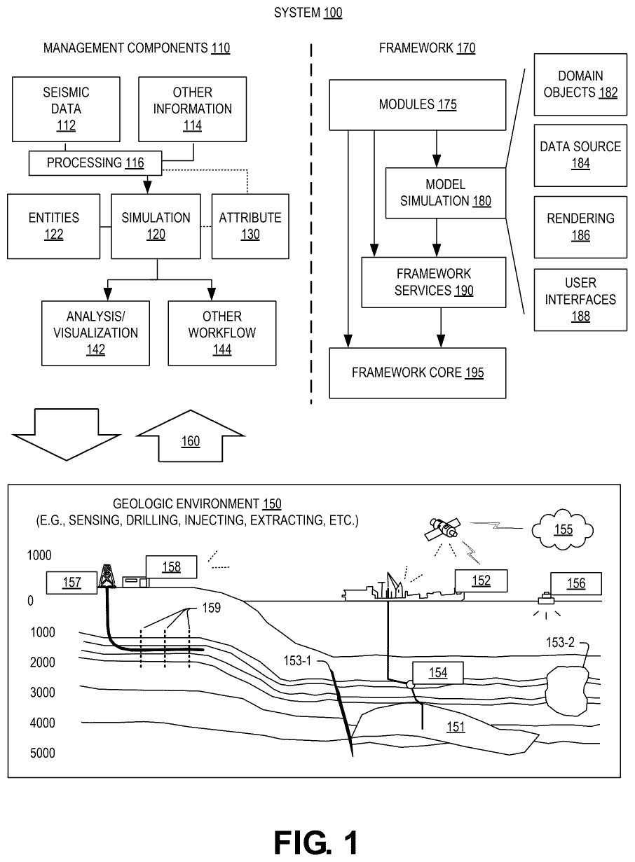

FIG. 1 illustrates an example of a system 100 that includes various management components 110 to manage various aspects of a geologic environment 150 (e.g., an environment that includes a sedimentary basin, a reservoir 151, one or more faults 153-1, one or more geobodies 153-2, etc.). For example, the management components 110 may allow for direct or indirect management of sensing, drilling, injecting, extracting, etc., with respect to the geologic environment 150. In turn, further information about the geologic environment 150 may become available as feedback 160 (e.g., optionally as input to one or more of the management components 110).

In the example of FIG. 1, the management components 110 include a seismic data component 112, an additional information component 114 (e.g., well/logging data), a processing component 116, a simulation component 120, an attribute component 130, an analysis/visualization component 142 and a workflow component 144. In operation, seismic data and other information provided per the components 112 and 114 may be input to the simulation component 120.

In an example embodiment, the simulation component 120 may rely on entities 122. Entities 122 may include earth entities or geological objects such as wells, surfaces, bodies, reservoirs, etc. In the system 100, the entities 122 can include virtual representations of actual physical entities that are reconstructed for purposes of simulation. The entities 122 may include entities based on data acquired via sensing, observation, etc. (e.g., the seismic data 112 and other information 114). An entity may be characterized by one or more properties (e.g., a geometrical pillar grid entity of an earth model may be characterized by a porosity property). Such properties may represent one or more measurements (e.g., acquired data), calculations, etc.

In an example embodiment, the simulation component 120 may operate in conjunction with a software framework such as an object-based framework. In such a framework, entities may include entities based on pre-defined classes to facilitate modeling and simulation. A commercially available example of an object-based framework is the MICROSOFT®.NET® framework (Redmond, Washington), which provides a set of extensible object classes. In the. NET® framework, an object class encapsulates a module of reusable code and associated data structures. Object classes can be used to instantiate object instances for use in by a program, script, etc. For example, borehole classes may define objects for representing boreholes based on well data.

In the example of FIG. 1, the simulation component 120 may process information to conform to one or more attributes specified by the attribute component 130, which may include a library of attributes. Such processing may occur prior to input to the simulation component 120 (e.g., consider the processing component 116). As an example, the simulation component 120 may perform operations on input information based on one or more attributes specified by the attribute component 130. In an example embodiment, the simulation component 120 may construct one or more models of the geologic environment 150, which may be relied on to simulate behavior of the geologic environment 150 (e.g., responsive to one or more acts, whether natural or artificial). In the example of FIG. 1, the analysis/visualization component 142 may allow for interaction with a model or model-based results (e.g., simulation results, etc.). As an example, output from the simulation component 120 may be input to one or more other workflows, as indicated by a workflow component 144.

As an example, the simulation component 120 may include one or more features of a simulator such as the ECLIPSE™ reservoir simulator (SLB, Houston Texas), the INTERSECT™ reservoir simulator (SLB, Houston Texas), etc. As an example, a simulation component, a simulator, etc. may include features to implement one or more meshless techniques (e.g., to solve one or more equations, etc.). As an example, a reservoir or reservoirs may be simulated with respect to one or more enhanced recovery techniques (e.g., consider a thermal process such as SAGD, etc.).

In an example embodiment, the management components 110 may include features of a commercially available framework such as the PETREL® seismic to simulation software framework (SLB, Houston, Texas). The PETREL® framework provides components that allow for optimization of exploration and development operations. The PETREL® framework includes seismic to simulation software components that can output information for use in increasing reservoir performance, for example, by improving asset team productivity. Through use of such a framework, various professionals (e.g., geophysicists, geologists, and reservoir engineers) can develop collaborative workflows and integrate operations to streamline processes. Such a framework may be considered an application and may be considered a data-driven application (e.g., where data is input for purposes of modeling, simulating, etc.).

In an example embodiment, various aspects of the management components 110 may include add-ons or plug-ins that operate according to specifications of a framework environment. For example, a commercially available framework environment marketed as the OCEAN® framework environment (SLB, Houston, Texas) allows for integration of add-ons (or plug-ins) into a PETREL® framework workflow. The OCEAN® framework environment leverages .NET® tools (Microsoft Corporation, Redmond, Washington) and offers stable, user-friendly interfaces for efficient development. In an example embodiment, various components may be implemented as add-ons (or plug-ins) that conform to and operate according to specifications of a framework environment (e.g., according to application programming interface (API) specifications, etc.).

FIG. 1 also shows an example of a framework 170 that includes a model simulation layer 180 along with a framework services layer 190, a framework core layer 195 and a modules layer 175. The framework 170 may include the commercially available OCEAN® framework where the model simulation layer 180 is the commercially available PETREL® model-centric software package that hosts OCEAN® framework applications. In an example embodiment, the PETREL® software may be considered a data-driven application. The PETREL® software can include a framework for model building and visualization.

As an example, a framework may include features for implementing one or more mesh generation techniques. For example, a framework may include an input component for receipt of information from interpretation of seismic data, one or more attributes based at least in part on seismic data, log data, image data, etc. Such a framework may include a mesh generation component that processes input information, optionally in conjunction with other information, to generate a mesh.

In the example of FIG. 1, the model simulation layer 180 may provide domain objects 182, act as a data source 184, provide for rendering 186 and provide for various user interfaces 188. Rendering 186 may provide a graphical environment in which applications can display their data while the user interfaces 188 may provide a common look and feel for application user interface components.

As an example, the domain objects 182 can include entity objects, property objects and optionally other objects. Entity objects may be used to geometrically represent wells, surfaces, bodies, reservoirs, etc., while property objects may be used to provide property values as well as data versions and display parameters. For example, an entity object may represent a well where a property object provides log information as well as version information and display information (e.g., to display the well as part of a model).

In the example of FIG. 1, data may be stored in one or more data sources (or data stores, generally physical data storage devices), which may be at the same or different physical sites and accessible via one or more networks. The model simulation layer 180 may be configured to model projects. As such, a particular project may be stored where stored project information may include inputs, models, results and cases. Thus, upon completion of a modeling session, a user may store a project. At a later time, the project can be accessed and restored using the model simulation layer 180, which can recreate instances of the relevant domain objects.

In the example of FIG. 1, the geologic environment 150 may include layers (e.g., stratification) that include a reservoir 151 and one or more other features such as the fault 153-1, the geobody 153-2, etc. As an example, the geologic environment 150 may be outfitted with any of a variety of sensors, detectors, actuators, etc. For example, equipment 152 may include communication circuitry to receive and to transmit information with respect to one or more networks 155. Such information may include information associated with downhole equipment 154, which may be equipment to acquire information, to assist with resource recovery, etc. Other equipment 156 may be located remote from a well site and include sensing, detecting, emitting or other circuitry. Such equipment may include storage and communication circuitry to store and to communicate data, instructions, etc. As an example, one or more satellites may be provided for purposes of communications, data acquisition, etc. For example, FIG. 1 shows a satellite in communication with the network 155 that may be configured for communications, noting that the satellite may additionally or instead include circuitry for imagery (e.g., spatial, spectral, temporal, radiometric, etc.).

FIG. 1 also shows the geologic environment 150 as optionally including equipment 157 and 158 associated with a well that includes a substantially horizontal portion that may intersect with one or more fractures 159. For example, consider a well in a shale formation that may include natural fractures, artificial fractures (e.g., hydraulic fractures) or a combination of natural and artificial fractures. As an example, a well may be drilled for a reservoir that is laterally extensive. In such an example, lateral variations in properties, stresses, etc. may exist where an assessment of such variations may assist with planning, operations, etc. to develop a laterally extensive reservoir (e.g., via fracturing, injecting, extracting, etc.). As an example, the equipment 157 and/or 158 may include components, a system, systems, etc. for fracturing, seismic sensing, analysis of seismic data, assessment of one or more fractures, etc.

As mentioned, the system 100 may be used to perform one or more workflows. A workflow may be a process that includes a number of worksteps. A workstep may operate on data, for example, to create new data, to update existing data, etc. As an example, a may operate on one or more inputs and create one or more results, for example, based on one or more algorithms. As an example, a system may include a workflow editor for creation, editing, executing, etc. of a workflow. In such an example, the workflow editor may provide for selection of one or more pre-defined worksteps, one or more customized worksteps, etc. As an example, a workflow may be a workflow implementable in the PETREL® software, for example, that operates on seismic data, seismic attribute(s), etc. As an example, a workflow may be a process implementable in the OCEAN® framework. As an example, a workflow may include one or more worksteps that access a module such as a plug-in (e.g., external executable code, etc.).

Drilling Planning System with Integrated Knowledge Management and Method for Using the Same

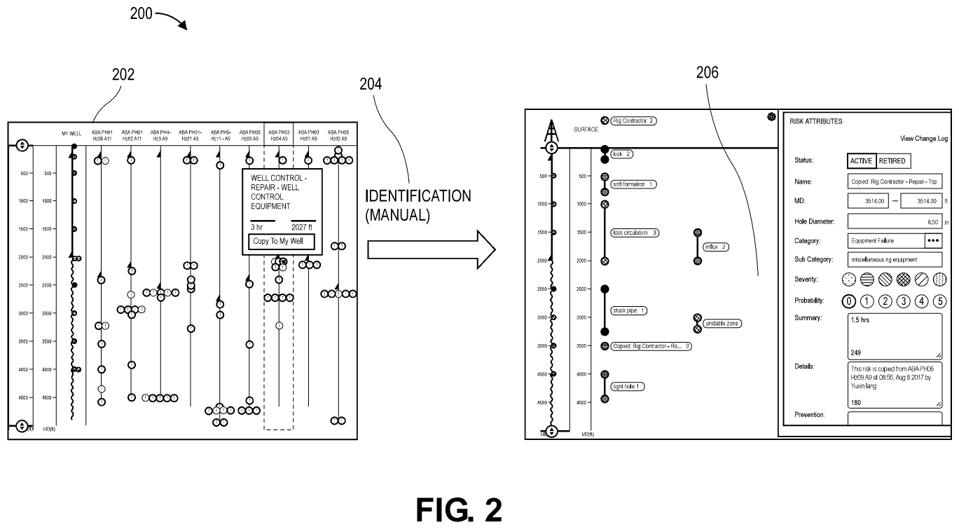

In a first embodiment, when preparing for a wellsite action such as planning a section of a well, a workflow 200 as seen in FIG. 2 is provided which involves users manually adding historical events as “relevant” to the planned section of the well. Specifically, the workflow 200 involves the user (1) reviewing the proposed well and each historical event of a plurality of offset wells in an analysis window 202 and assessing whether, if some mitigation or prevention measures are applied, the event would then be more or less likely to occur within the planned well, and (2) recording and then approving the planned mitigation or prevention measures in an approval widow 206. To find the relevant mitigation or prevention measures, the user may first manually connect to a knowledge management system 204 and then perform a keyword search for mitigation or prevention measures which may apply.

In a second embodiment, the system and method may provide a structured or contextualized database within a knowledge management system. Specifically, a method is provided for performing a semi-structured semantic search within a vectorized knowledge bank in order to return the most relevant mitigation and/or prevention measures related to the planned wellsite action.

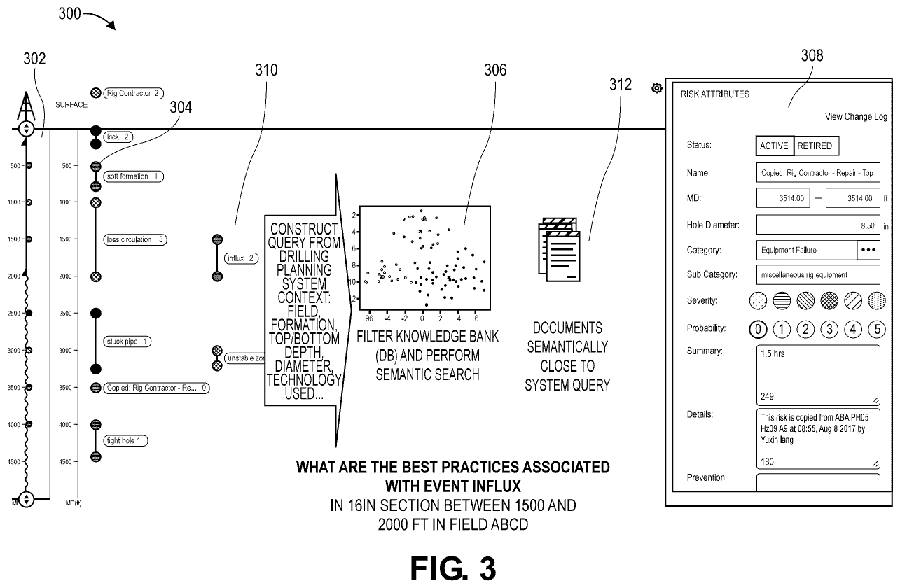

According to certain embodiments, the method generates a set of system queries constructed from the characteristics of a wellsite action, for example when planning or designing a section of a well. As seen in the illustration of FIG. 3, a user begins by inputting a number of characteristics or features of the planned section of the well, for example the location or field the well will be disposed in, a proposed diameter of the planned section diameter, and the like, into an input field 302 of a graphical interface 300 that is displayed on a display that is within the system 100. According to certain embodiments, the input field 302 may be arranged to illustratively depict which characteristics are present at which corresponding depths of the planned well. In certain embodiments, risks that are associated with the input characteristics are then populated into the graphical interface 300 in a risk column 304 that is aligned with the input field 302, thereby denoting which risks are present at which depths of the planned well. Which risks are likely at which depths are taken from data related to a plurality of offset wells that is stored within a risk register within the system 100, FIG. 1.

Further details for each risk may be seen by selecting one of the populated risks which in turn displays a risk detail window 308 which gives the user additional information about that specific risk or type of risk. In certain embodiments, the risks displayed within the risk column 304 are displayed with a visual indicator corresponding to a risk level. In some embodiments, the relative risk level of each risk displayed within the risk column 304 is color coded, for example, with green representing a low risk, yellow representing a medium risk, and red representing a high risk. The risk level may be determined by the proximity of the data retrieved from the risk register relative to the planned well section, a probability of the risk occurring, a likely severity if the risk did occur, or a combination thereof. The risk level and the data which is used to determine the risk level for any selected risk may be displayed within the risk detail window 308, according to certain embodiments.

According to certain embodiments, mitigation and prevention measures which correspond to the risk column 304 are obtained by first converting the risks within the risk column 304 into a query vector. The query vector is then inserted into a vectorized representation of a knowledge bank 306 as seen in FIG. 3. The knowledge bank 306 is queried by processors within the system 100 and nearby vectors are returned to the user, each returned vector representing a proposed mitigation and/or prevention measure that is correlated or associated with the section scope of work, i.e. the characteristics input into the input field 302. According to certain embodiments, the system 100 uses a semantic search using an Approximate Nearest Neighbor (ANN) AI approach, which allows for a search for points in space that are close to a given query point and to return to the user the most relevant mitigation or prevention measure contained within the knowledge bank 306. According to certain embodiments, the semantic search returns three closest vectors in space relative to the original query vector, the three closest vectors representing mitigation or prevention measures that are the most semantically similar to an event that occurred in the past to what is currently happening or to what the most likely risks are for the planned well section. According to some embodiments, the three closest vectors that are returned may include a proximity of a known risk to the planned well section, a severity of a known risk related to the planned well section, a probability of risk occurring in the planned well section, or a combination thereof. According to some embodiments, the most relevant mitigation or prevention measures found within the knowledge bank 306 are distributed in a results column 310 within the graphical interface 300. In some embodiments, the results column 310 may be aligned with the risk column 304 so that the mitigating or preventing measures may be displayed at the corresponding depth of the planned section of the well. In certain embodiments, a document, link, or other reference item 312 related to the mitigation or prevention measure is provided to the user within the graphical interface 300.

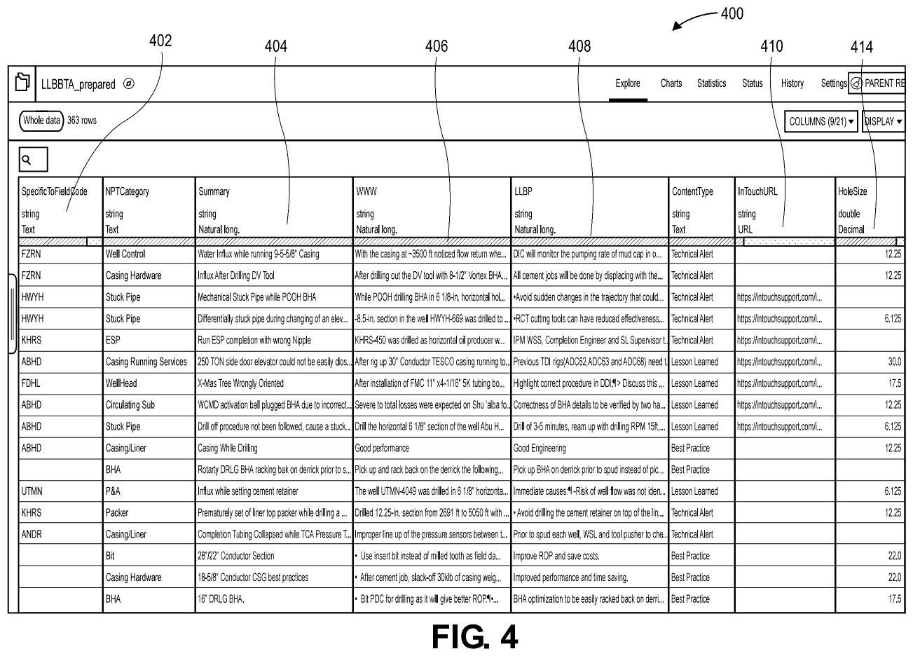

In certain embodiments, the knowledge bank 306 may be represented by a structural database 400 as seen in FIG. 4. In some embodiments, the structural database 400 is a table which lists each risk within the knowledge bank 306 according to an assigned field code 402. For each field code 402, a corresponding summary 404 is given which provides further information on the risks associated with the planned section of the well. According to certain embodiments, a particular event associated with a certain risk may have already occurred, in which case a description of the event is given within an event column 408. In certain embodiments, the semantic search as described above is performed, and the most relevant mitigation measures and/or prevention measures are given within results column 408 for each field code 402. According to some embodiments, a link 410 may be provided for one or more of the field codes 402, the link 410 directing the user to additional information such as, for example, the document or other reference 312 that may be displayed within the graphical interface 300.

According to certain embodiments, each of the mitigation or prevention measures are provided with a category 412 which denotes if the mitigation or prevention measure is a best practice which is a general procedure for mitigating or preventing risks, a lesson learned which is a practice that has been done previously in response to a prior historical event, or a standard operating procedure which is a precise or specific series of steps for addressing. In further embodiments, a hole size 414 is given for each field code 402. Both the category 412 and the hole size 414 can be used to further filter or refine the search results or other information contained within the structural database 400.

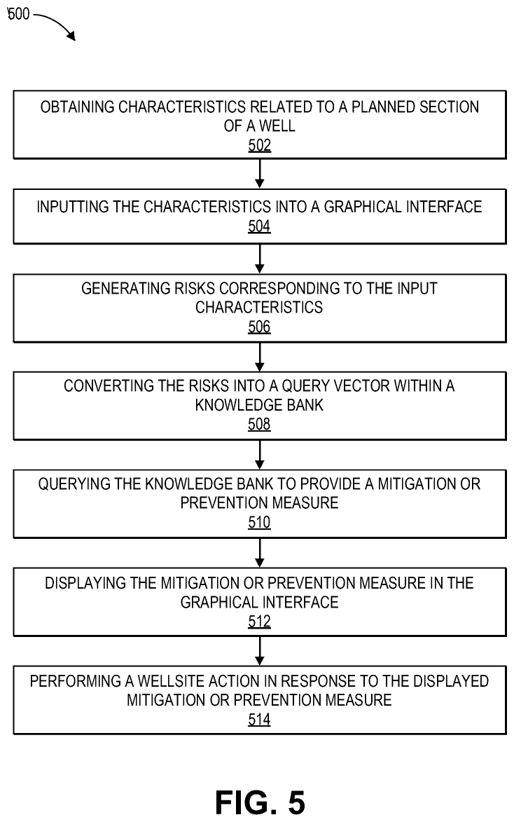

FIG. 5 illustrates a flowchart of a method 500 for automatically determining mitigation and prevention measures related to a planned section of a well or other wellsite action. According to certain embodiments, the method 500 includes obtaining a plurality of characteristics of the wellsite action, as at 502. In certain embodiments, the characteristics of the wellsite action include but are not limited to a depth of a planned section of a well, a formation of a planned section of the well, a diameter of a planned section of a well, a tool that may be used in the formation of a planned section of the well, a field that a planned section of a well is to be disposed in, a shape of the planned section of a well, or combinations thereof.

According to certain embodiments, the method 500 includes inputting the characteristics of the planned section of the well into the graphical interface 300, as at 504. In certain embodiments, the graphical interface 300 is displayed on a display of the system 100 and associated with a user. Inputting the characteristics into the graphical interface 300 may be done manually by the user, or automatically upon receipt of an outside signal received from tools, systems, or sensors communicated to the system 100.

According to certain embodiments, the method 500 includes generating a plurality of risks that correspond to the plurality of characteristics and then displaying the plurality of risks on the graphical interface 300, as at 506. In certain embodiments, generating the plurality of risks may include automatically incorporating at least one risk that is known to be associated with a specific characteristic of the planned section of the well as stored on a memory within the system 100, or alternatively, manually inputting at least one risk as known to the user.

According to certain embodiments, the method 500 includes converting the plurality of risks into a query vector within a knowledge bank 306, as at 508. Additionally, the method 500 includes querying the knowledge bank 306 to provide at least one mitigation measure or prevention measure that is relevant to at least one of the risks that has been associated with the characteristics of the wellsite action, as at 510. In certain embodiments, querying the knowledge bank 306 may include performing a semantic search. More specifically, performing a semantic search may include performing an approximate nearest neighbor (ANN) search within the knowledge bank 306. In certain embodiments, the ANN search searches for three vectors representing mitigation or prevention measures within the knowledge bank 306 that are the closest semantically to the query vector.

According to certain embodiments, the method 500 includes displaying the found mitigation or prevention measures within the graphical interface 300, as at 512. Next, the method 500 further includes performing a wellsite action in response to the query vector (508), the mitigation measure or prevention measure (510), and/or the displayed mitigation or prevention measures (512), as at 514. In certain embodiments, performing the wellsite action may include generating or transmitting a signal that instructs or causes an action to occur. The action may include a physical action. The physical action may include selecting where to drill a wellbore in the subsurface formation, drilling the wellbore, varying a trajectory of the wellbore, varying a weight or torque on a drill bit that is drilling the wellbore, varying a rate or concentration of a fluid being pumped into the wellbore, or a combination thereof.

### Exemplary Computing System

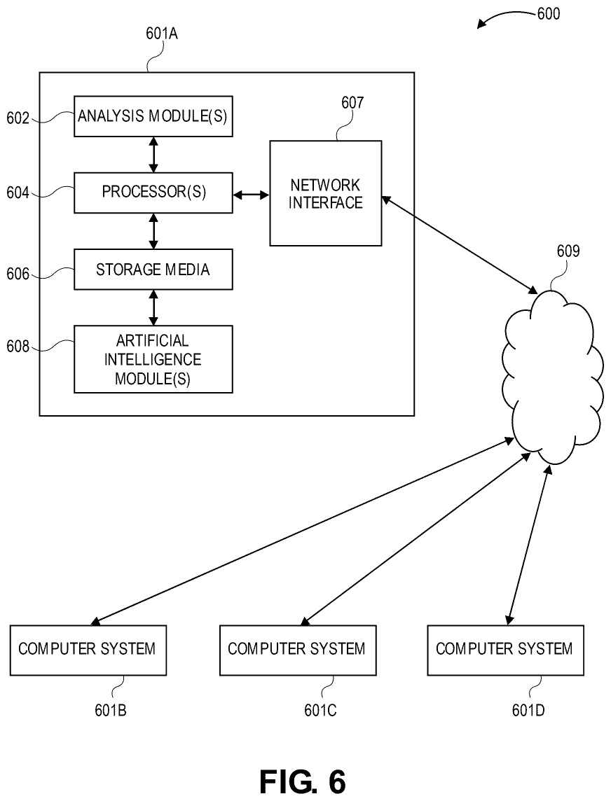

In some embodiments, the methods of the present disclosure may be executed by a computing system. FIG. 6 illustrates an example of such a computing system 600, in accordance with some embodiments. The computing system 600 may include a computer or computer system 601A, which may be an individual computer system 601A or an arrangement of distributed computer systems. The computer system 601A includes one or more analysis modules 602 that are configured to perform various tasks according to some embodiments, such as one or more methods disclosed herein. To perform these various tasks, the analysis module 602 executes independently, or in coordination with, one or more processors 604, which is (or are) connected to one or more storage media 606. The processor(s) 604 is (or are) also connected to a network interface 607 to allow the computer system 601A to communicate over a data network 609 with one or more additional computer systems and/or computing systems, such as 601B, 601C, and/or 601D (note that computer systems 601B, 601C and/or 601D may or may not share the same architecture as computer system 601A, and may be located in different physical locations, e.g., computer systems 601A and 601B may be located in a processing facility, while in communication with one or more computer systems such as 601C and/or 601D that are located in one or more data centers, and/or located in varying countries on different continents).

A processor may include a microprocessor, microcontroller, processor module or subsystem, programmable integrated circuit, programmable gate array, or another control or computing device.

The storage media 606 may be implemented as one or more computer-readable or machine-readable storage media. Note that while in the example embodiment of FIG. 6 storage media 606 is depicted as within computer system 601A, in some embodiments, storage media 606 may be distributed within and/or across multiple internal and/or external enclosures of computing system 601A and/or additional computing systems. Storage media 606 may include one or more different forms of memory including semiconductor memory devices such as dynamic or static random access memories (DRAMs or SRAMs), erasable and programmable read-only memories (EPROMs), electrically erasable and programmable read-only memories (EEPROMs) and flash memories, magnetic disks such as fixed, floppy and removable disks, other magnetic media including tape, optical media such as compact disks (CDs) or digital video disks (DVDs), BLURAY® disks, or other types of optical storage, or other types of storage devices. Note that the instructions discussed above may be provided on one computer-readable or machine-readable storage medium, or may be provided on multiple computer-readable or machine-readable storage media distributed in a large system having possibly plural nodes. Such computer-readable or machine-readable storage medium or media is (are) considered to be part of an article (or article of manufacture). An article or article of manufacture may refer to any manufactured single component or multiple components. The storage medium or media may be located either in the machine running the machine-readable instructions, or located at a remote site from which machine-readable instructions may be downloaded over a network for execution.

In some embodiments, computing system 600 contains one or more method execution module(s) 608. In the example of computing system 600, the computer system 601A includes the method execution module 608. In some embodiments, a single method execution module may be used to perform some aspects of one or more embodiments of the methods disclosed herein. In other embodiments, a plurality of method execution modules may be used to perform some aspects of methods herein.

It should be appreciated that computing system 600 is merely one example of a computing system, and that computing system 600 may have more or fewer components than shown, may combine additional components not depicted in the example embodiment of FIG. 6, and/or computing system 600 may have a different configuration or arrangement of the components depicted in FIG. 6. The various components shown in FIG. 6 may be implemented in hardware, software, or a combination of both hardware and software, including one or more signal processing and/or application specific integrated circuits.

Further, the steps in the processing methods described herein may be implemented by running one or more functional modules in information processing apparatus such as general purpose processors or application specific chips, such as ASICs, FPGAS, PLDs, or other appropriate devices. These modules, combinations of these modules, and/or their combination with general hardware are included within the scope of the present disclosure.

Computational interpretations, models, and/or other interpretation aids may be refined in an iterative fashion; this concept is applicable to the methods discussed herein. This may include use of feedback loops executed on an algorithmic basis, such as at a computing device (e.g., computing system 600, FIG. 6), and/or through manual control by a user who may make determinations regarding whether a given step, action, template, model, or set of curves has become sufficiently accurate for the evaluation of the subsurface three-dimensional geologic formation under consideration.

The foregoing description, for purpose of explanation, has been described with reference to specific embodiments. However, the illustrative discussions above are not intended to be exhaustive or limiting to the precise forms disclosed. Many modifications and variations are possible in view of the above teachings. Moreover, the order in which the elements of the methods described herein are illustrated and described may be re-arranged, and/or two or more elements may occur simultaneously. The embodiments were chosen and described in order to best explain the principles of the disclosure and its practical applications, to thereby enable others skilled in the art to best utilize the disclosed embodiments and various embodiments with various modifications as are suited to the particular use contemplated.

What is claimed is:

1. A method for automatically determining mitigation and prevention measures related to a wellsite action, the method comprising:
obtaining a plurality of characteristics of the wellsite action;
generating a plurality of risks corresponding to the plurality of characteristics;
converting the plurality of risks into a query vector within a knowledge bank; and
querying the knowledge bank to provide at least one mitigation or prevention measure in response to the query vector.

2. The method of claim 1, wherein the plurality of characteristics of the wellsite action comprises at least one of the following:
a depth of a planned section of a well;
a formation of a planned section of the well;
a diameter of a planned section of a well;
a tool to be used in a planned section of the well;
a field of a planned section of a well; or
a shape of a planned section of a well.

3. The method of claim 1, further comprising:
inputting the plurality of characteristics into a graphical interface;
displaying the plurality of risks on the graphical interface; and
displaying the mitigation or prevention measure on the graphical interface.

4. The method of claim 3, wherein inputting the plurality of characteristics into the graphical interface comprises manually inputting the plurality of characteristics.

5. The method of claim 3, wherein inputting the plurality of characteristics into the graphical interface comprises automatically receiving an input from a tool, system, or sensor associated with the wellsite action.

6. The method of claim 1, wherein generating the plurality of risks comprises automatically incorporating at least one known risk associated with at least one offset well or manually inputting at least one known risk by a user.

7. The method of claim 1, wherein querying the knowledge bank to provide at least one mitigation or prevention measure relevant to the query vector comprises performing a semantic search within the knowledge bank.

8. The method of claim 7, wherein performing the semantic search within the knowledge bank comprises performing an approximate nearest neighbor search within the knowledge bank.

9. The method of claim 8, wherein performing an approximate nearest neighbor search within the knowledge bank comprises performing a search for three closest vectors within the knowledge bank relative to the query vector to provide the at least one mitigation or prevention measure that is most relevant to the query vector.

10. The method of claim 9, wherein the three closest vectors within the knowledge bank relative to the query vector comprises:
a proximity of a known risk to a planned well section;
a severity of a known risk related to the planned well section;
a probability of risk occurring in the planned well section:
or a combination thereof.

11. The method of claim 1, further comprising performing a wellsite action by generating or transmitting a signal that instructs or causes an action to occur, wherein the action comprises a physical action, and wherein the physical action comprises selecting where to drill a wellbore in a subsurface formation, drilling the wellbore, varying a trajectory of the wellbore, varying a weight or torque on a drill bit that is drilling the wellbore, varying a rate or concentration of a fluid being pumped into the wellbore, or a combination thereof.

12. A computing system, comprising:
one or more processors;
a memory system comprising one or more non-transitory computer-readable media storing instructions that, when executed by at least one of the one or more processors, cause the computing system to perform operations, the operations comprising:
obtaining a plurality of characteristics of a wellsite action;
inputting the plurality of characteristics into a graphical interface;
generating a plurality of risks corresponding to the plurality of characteristics and displaying the plurality of risks on the graphical interface;
converting the plurality of risks into a query vector within a knowledge bank;
querying the knowledge bank to provide at least one mitigation or prevention measure relevant to the query vector;
displaying the mitigation or prevention measure within the graphical interface; and
performing a wellsite action in response to the displayed mitigation or prevention measure.

13. The computing system of claim 12, wherein displaying the plurality of risks on the graphical interface comprises displaying a corresponding risk level associated with each of the plurality of risks.

14. The computing system of claim 12, further comprising categorizing each of the mitigation or prevention measures as a best practice, a lesson learned, or a standard operating procedure.

15. The computing system of claim 13, wherein the operations further comprise filtering the prevention or mitigation measures according to at least one characteristic of the wellsite action.

16. The computing system of claim 12, wherein displaying the plurality of risks on the graphical interface comprises displaying a proximity of a risk relative to the input characteristics of the wellsite action, a severity of a risk relative to the input characteristics of the wellsite action, or a probability of a risk relative to the input characteristics of the wellsite action.

17. A non-transitory computer-readable medium storing instructions that, when executed by one or more processors of a computing system, cause the computing system to perform operations, the operations comprising:
obtaining a plurality of characteristics of a wellsite action;
inputting the plurality of characteristics into a graphical interface;
generating a plurality of risks corresponding to the plurality of characteristics and displaying the plurality of risks on the graphical interface;
converting the plurality of risks into a query vector within a knowledge bank;
querying the knowledge bank to provide at least one mitigation or prevention measure relevant to the query vector;
displaying the mitigation or prevention measure within the graphical interface; and
performing a wellsite action in response to the displayed mitigation or prevention measure.

18. The non-transitory computer-readable medium of claim 17, wherein displaying the mitigation or prevention measure within the graphical interface comprises displaying a document within the graphical interface or providing a link to a reference item within the graphical interface.

19. The non-transitory computer-readable medium of claim 17, wherein displaying the plurality of risks on the graphical interface and displaying the mitigation or prevention measure within the graphical interface comprises displaying the risks and the mitigation or prevention measure at a depth of the wellsite action which corresponds to a depth of at least one of the characteristics of the wellsite action.

20. The non-transitory computer-readable medium of claim 17, wherein performing the wellsite action comprises generating or transmitting a signal that instructs or causes an action to occur, wherein the action comprises a physical action, and wherein the physical action comprises selecting where to drill a wellbore in a subsurface formation, drilling the wellbore, varying a trajectory of the wellbore, varying a weight or torque on a drill bit that is drilling the wellbore, varying a rate or concentration of a fluid being pumped into the wellbore, or a combination thereof.
